(19) United States
(12) Patent Application Publication
(10) Pub. No.: US 2005/0087892 A1
(43) Pub. Date: Apr. 28, 2005

(54) [NAND FLASH MEMORY CELL ROW, NAND FLASH MEMORY CELL ARRAY, OPERATION AND FABRICATION METHOD THEREOF]

(76) Inventors: Cheng-Yuan Hsu, Hsinchu City (TW); Chih-Wei Hung, Hsinchu City (TW); Da Sung, Hsinchu (TW); Min-San Huang, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/709,125

(22) Filed: Apr. 15, 2004

(30) Foreign Application Priority Data
Oct. 27, 2003 (TW) 92129718

(51) Int. Cl. H01L 27/10

(52) U.S. Cl. 257/909

(57) ABSTRACT

A NAND flash memory cell array including a plurality of memory cell row is provided. Each of memory cell row includes a plurality of memory cells disposed between first selecting transistor and second selecting transistor connected in series. Each memory cell has a tunneling dielectric layer, a floating gate, an inter-gate dielectric, a control gate and source/drain regions. An erase gate is disposed between two adjacent memory cells. A plurality of word lines serve to connect the memory cells in rows. A source line serves to connect the source region of the first transistor in a row, whereas a plurality of bit lines serve to connect the drain region of second transistor in a row. A first selecting gate line and a second selecting gate line serve to connect the gate of the first transistor in a row and the gate of second transistor in a row respectively. A plurality of erase gate lines is connected to the erase gates in a row.

### CROSS REFERENCE TO RELATED APPLICATIONS

This application claims the priority benefit of Taiwan application serial no. 92129718, filed Oct. 27, 2003.

### BACKGROUND OF INVENTION

1. Field of the Invention

This present invention relates to a memory cell device, and more particularly to a NAND flash memory cell array, and operation and fabrication method thereof.

2. Description of Related Art

Flash memory device has superior multi-access characteristics, including write, read and erase data, and data is retained in the cell even when power to the flash memory is turned off. Therefore, flash memory has been broadly used as non-volatile memory device in personal computers and other electronic appliances.

A typical flash memory device is a stacked structure comprising a tunnel oxide, a dielectric layer, floating gate and a control gate, both comprised of doped polysilicon. The control gate is disposed over the floating gate. The dielectric layer is disposed in between the control gate and the floating gate. The tunnel oxide is sandwiched between the floating gate and the substrate.

In order for flash memory to perform the “write” operation, a bias voltage is applied to control gate and drain/source regions, an operating voltage is applied to the control gate and the substrate is connected to the ground, so that the electrons are injected into floating gate and the charging status of the floating gate affects switch on/off of the channel underneath, i.e. the on/off status of the channel serves to determine the data being “0” or “1”. In order for the flash memory to perform an “erase” operation, the voltage of the substrate and the drain/source regions or the control gate are raised relatively, so that electrons penetrates through the tunneling oxide layer via tunneling effect into the drain/source regions, and this phenomena is referred to as substrate erase or drain/source side erase; or the electrons penetrates through the dielectric layer into the control gate.

The flash memory array that is popularly used in the industry includes a NOR gate array structure and a NAND array structure. Since a NAND array is structured with the memory cells connected in series, it can provide a higher storage density compared to the NOR array structure. However, in the NAND array the programming, reading, and erasing operations of memory cells are more complicated. Generally speaking, in a NAND array structure, program and erase operations are accomplished via F-N (Fowler-Nordheim) tunneling effect, in which electrons penetrates through the tunneling oxide layer into the floating gate, and the electrons are drawn into the substrate there-through. Therefore, since tunneling oxide layer is operated under high voltage, and therefore may get easily damaged and thereby the reliability of the device is reduced. Besides, memory cells are connected in series in an array, some distributed reading current for individual cell is relatively small, which lowers the operation speed, and thus, the efficiency of the device is down-graded.

### SUMMARY OF INVENTION

Accordingly, the present invention is related to a NAND flash memory cell row, a NAND flash memory array and operation and fabrication method thereof. The process of fabricating the NAND array structure is simplified, the programming speed of the memory cell is increased and the efficiency of the memory cell is enhanced.

In an embodiment of the present invention, the structure of the NAND flash memory cell row, NAND flash memory cell array is capable of enhancing efficiency of the device and also capable of increasing the integration of the device.

The NAND flash memory cell array comprises a plurality of gate structures. Each gate structure comprises at least a tunneling dielectric layer, a floating gate, an inter-gate dielectric layer, and a control gate. A plurality of doped regions is disposed in the substrate between the gate structures respectively. The gate structures are connected in series. A plurality of erase gates is disposed over the doped regions respectively. A spacer is disposed between the gate structure and the erase gate. The Dielectric layer is disposed between the erase gate and the doped region.

A first select gate and a second select gate are respectively disposed on the sidewalls of the outermost two gate structures. A select gate dielectric layer is disposed between the substrate and the first select gate, the second select gate. A drain region is disposed on one side of the substrate of the first select gate apart from the outermost gate structure. A source region is disposed on one side of the substrate of the second select gate apart from the outermost gate structure.

In the aforementioned NAND flash memory cell row, an erase gate is disposed over the doped (source/drain) regions. Therefore, when the memory cells are performing erase operation, electrons are drawn from the floating gate to the erase gate via F-N tunneling effect, and thus are removed. Since electrons are removed via erase gate in the present invention, instead of being removed via the substrate by penetrating the tunneling oxide layer, deep n-well in the substrate is thus not required; moreover, exposed N-well region need not be formed in the peripheral area of the memory cell array. A NAND flash memory cell array comprises a plurality of memory cells that is disposed two-dimensionally. Each of the memory cells includes a plurality of gate structures, each gate structure includes tunneling dielectric layer, floating gate, inter-gate dielectric layer, and control gate, which are disposed on the substrate sequentially. A plurality of doped regions is disposed in the substrate between gate structures respectively, and the gate structures are connected in series. A plurality of erase gates is disposed between the gate structures and over the doped regions respectively. A spacer is disposed between the gate structure and the erase structure. The dielectric layer is disposed between the erase gate and the doped region. A first select gate and a second select gate are disposed respectively on sidewalls of the two outermost gate structures. A select gate dielectric layer is disposed between the substrate of the first select gate and the second select gate. A drain region is disposed in one side of the substrate of the first select region being not adjacent to outer gate structure. A source region is disposed in the substrate of the second select gate being not adjacent to outer gate structure. A plurality of word lines is arranged in parallel along columns, and couples to control gate of the gate structure within the same column. A plurality of bit lines is coupled to the drain regions of the first select gates respectively within the same column. A source line is coupled to the source regions of the second select gates respectively within the same column. A plurality erase gate lines is arranged in parallel along columns, and couples to the erase gates within the same column.

In the foregoing NAND flash memory cell array, the erase gate is disposed over doped regions (source/drain regions), therefore when the memory cell is performing erase operation, electrons are drawn from the floating gate to the erase gate and removed therefrom via F-N tunneling effect. Since electrons are removed via erase gate in the present invention, instead of being removed via tunneling oxide, thus deep n-well need not be formed in the substrate. Moreover, exposed N-well region need not be formed on the peripheral area, and therefore this allows further integration of the device. An erase gate is jointly used by adjacent gate structures, thus this design does not consume additional chip space.

The method of fabricating the NAND flash memory cell is provided is described as follows. A plurality of gate structures is formed in a row over the substrate. The gate structure includes a tunneling dielectric layer, a floating gate, an inter-gate dielectric layer and a control gate, sequentially formed on the substrate. Next, a dielectric layer is formed over the doped regions, and then a first spacer is formed on the sidewalls of the floating gate. Next, an erase gate is formed between the gate structures, and a second spacer is formed on the sidewalls of the two outermost gate structures. Thereafter, a select gate dielectric is formed over the substrate, and a first select gate and a second select gate are formed on the sidewall of the second spacer. A source/drain region is formed in the substrate of the first select gate and the second select gate being not adjacent to the gate structure. Next, a source line is formed on the substrate connecting the source regions.

In the foregoing description, the erase gate is formed over the doped regions (i.e. source/drain regions, between gate structures). Therefore, when memory cells perform erase operation, electrons are drawn from the floating gate to the erase gate via F-N tunneling effect.

Moreover, deep N-well and the exposed N-well regions on the peripheral area need not formed, and therefore, this allows further increase in the integration of the device. Besides, an erase gate is jointly used directly by adjacent two gate structures, thus this design will not increase space occupation on the chip. Furthermore, the floating gate is comprised of a polycrystalline layer doped with arsenic, thus by forming inter-gate dielectric between floating gate and the erase gate, a circular shaped erase gate can be formed for providing better erase operation.

An operating method of the NAND flash memory cell array is also provided in the present invention. For program operation, a zero voltage is applied to the selected bit line, a first voltage is applied to a non-selected bit line, a second voltage is applied to the first gate line, a third voltage is applied to the word line that is coupled to the selected memory cell, and a fourth voltage is applied to the non-select bit line, so as to program the selected memory cell via F-N tunneling effect. For read operation, a fifth voltage is applied to the selected bit line, a sixth voltage is applied to the first select gate line, a zero voltage is applied to the word line coupling to the selected memory cell, a seventh voltage is applied to the non-selected word line so as to read the memory cell. For erase operation, an eighth voltage is applied to the erase gate line, which voltage differs to the substrate voltage by an amount sufficiently inject electrons to the floating gate of the memory cell, so that electrons are removed via erase gate, as well as the entire memory cell array.

According to an embodiment of the present invention, during the operation of the NAND flash memory cell array, electrons penetrate the tunneling dielectric layer and are injected into the floating gate via F-N tunneling effect, so as to program the memory cell. On the other hand, electrons are drawn from the floating gate penetrating the inter-gate dielectric and are injected into erase gate via F-N tunneling effect, so as to erase the memory cell. Since amount of electron penetration through the tunneling dielectric layer is substantially reduced, and therefore the lifetime or the service life of the tunneling dielectric layer can be further extended, and also reliability of the device can be enhanced. Moreover, since electrons injections via F-N tunneling effect provides higher efficiency, therefore the operating current is reduced and thereby the operating speed is increased. Furthermore, since programming and erasing are accomplished via F-N tunneling effect, therefore the overall power consumption is reduced.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF DRAWINGS

FIG. 1 is a circuit diagram illustrating a NAND flash memory cell array according to one embodiment of the present invention.

FIG. 2 is cross section view of a NAND flash memory cell array according to one embodiment of the present invention.

FIG. 3A to 3G are cross section views of a NAND flash memory cell array illustrating progression of process steps according to one embodiment of the present invention.

### DETAILED DESCRIPTION

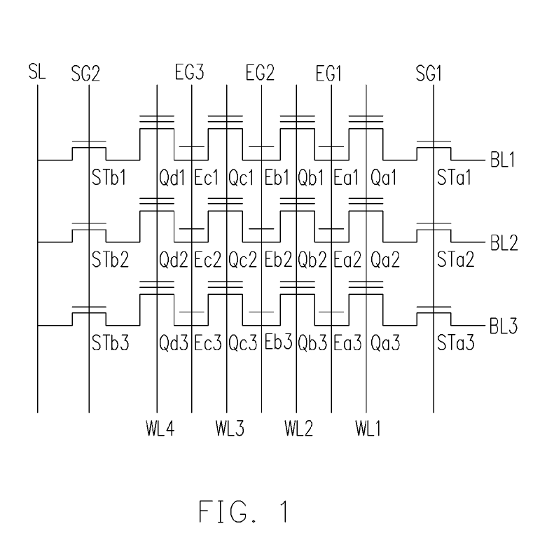

FIG. 1 shows a circuit diagram of a NAND flash memory cell array according to one invention of the present invention. Three rows of NAND memory cells are exemplary in this embodiment for following description.

Referring to FIG. 1, a NAND flash memory cell array includes a plurality of select transistors STa1˜STa3 and STb1˜STb3, a plurality of memory cells Qa1˜Qd3, a plurality of word lines WL1˜WL4, two select gate lines SG1 and SG2, bit lines BL1˜BL3 and erase gate lines EG1˜EG3.

The memory cell Qa1˜Qd1 are arranged in a row, and are connected in series between the select transistor STa1 and the select transistor STb1. The memory cell Qa2˜Qd2 are arranged in a row, and are connected in series between the select transistor STa2 and the select transistor STb2. The memory cells Qa3˜Qd3 are arranged in a row, and are connected in series between the select transistor STa3 and the select transistor STb3.

A plurality of word lines are arranged in parallel along the columns, and a word line of a column is connected to the gates of the memory cells in the same column. That is, the gates of the memory cells Qa1˜Qa3 in the first column are coupled to the word line WL1. The gates of the memory cells Qb1˜Qb3 in the second column are coupled to the word line WL2. The gates of the memory cells Qc1˜Qc3 in the third column are coupled to the word line WL3. The gates of the memory cells Qd1˜Qd3 in the fourth column are coupled to the word line WL4.

The gates of the select transistors STa1˜STa3 are coupled to the select gate line SG1. The drains of the select transistors STa1˜STa3 are respectively coupled to the bit lines BL1˜BL3. The gates of the select transistors STb1˜STb3 are coupled to the select gate line SG1. The sources of the select transistors STb1˜STb3 are coupled to the source line SL. An erase gate is disposed between two adjacent memory cells in the same row, that is, erase gates Ea1˜Ec1 are disposed between Qa1˜Qd1; erase gates Ea2˜Ec2 are disposed between Qa2˜Qd2; and erase gates Ea3˜Ec3 are disposed between Qa3˜Qd3. A plurality of erase gate lines is arranged in parallel along the columns, and an erase gate line of a column is coupled to the erase gates of the same column. That is, the erase gates Ea1˜Ea3 are coupled to the erase gate line EG1 in the first column, the erase gates Eb2˜Eb2 are coupled to the erase gate line EG2 in the second column, and the erase gates Ec1˜Ec3 are coupled to the erase gate line EG3 in the third column.

The programming, erasing and reading operations of the NAND flash memory cell array is described taking the memory cell Qb2 with reference to FIG. 1 and table 1.

TABLE 1

| | PROGRAM | ERASE | READ |
|---|---|---|---|
| Selected word line | +V_{gp} | 0 | 0 |
| WL2 | | | |
| Non-selected word | +V_{g} | 0 | +V_{g} |
| WL1, WL3, WL4 | | | |
| Selected bit line | 0 | 0 | +V_{br} |
| BL2 | | | |
| Non-selected bit line | +Vb | 0 | 0 |
| BL1, BL3 | | | |
| Select gate line | Vₛₜ | 0 | Vst |
| SG1 | | | |
| Select gate line | 0 | 0 | Vst |
| SG2 | | | |
| Source line | 0 | floating | 0 |
| SL | | | |
| Erase gate line | 0 | +V_{ge} | 0 |
| EG1, EG2, EG3 | | | |

Referring to FIG. 1 again, for programming operation, a bias voltage +V_{gp}, for example, about 10 to 20 volts, is applied to the select word line WL2. A bias voltage +V_{g}, for example, about 5 to 7 volts, is applied to non-selected word lines WL1, WL3 and WL4 to turn on the channels of the non-selected memory cells. A bias voltage +Vₛₜ, for example, 10 to 20 volts, is applied to the select gate lines SG1 to turn on the channels of the select transistors STa1˜STa3. Thus the bit lines BL1˜BL3 are respectively electrical coupled to the memory cells Qa1˜Qd1, the memory cells Qa2˜Qd2 and the memory cells Qa3˜Qd3. The select gate line SG2 is biased to, for example, a zero voltage. The selected bit line BL2 is biased to a zero voltage. A bias voltage +V_{b}, for example, 5 to 7 volts is applied to the non-selected bit lines BL1 and BL3. The source line SL is biased to zero voltage. The erase gate lines EG1˜EG3 are biased to zero voltage. Under the above condition, a large field is built up between the floating gate of the selected memory cell Qb2 and the substrate, so that the electrons penetrate into the floating gate via F-N tunneling effect.

During the foregoing programming step, the word line WL2, which is jointly used by the memory cells Qb1 and Qb3, is not programmed. This is because the non-selected bit lines BL1 and BL3 are biased to 5 to 7 volts, and therefore this high voltage potential between the floating gate and the substrate functions as a shield against the F-N tunneling effect, thus the programming of the memory cells Qb1 and Qb3 can be prevented.

Furthermore, the non-selected word lines WL1, WL3 and WL4 are biased to 5 to 7 volts for turning on the channels of the memory cells and not for inducing F-N tunneling effect. Therefore, the memory cells Qa1˜Qa3, Qc1˜Qc3 and Qd1˜Qd3 coupled to the non-selected word lines WL1, WL3 and WL4 during the aforementioned programming step are not programmed.

In the foregoing descriptions, a single memory cell in the memory cell device is treated as a unit for programming. In the present embodiment, the NAND flash memory cell array can be programmed by controlling each of the word lines, the select gate lines and the bit lines for programming a byte, a section or a block as a unit.

For reading data from the memory cell Qb2, a bias voltage +Vₛₜ,for example, about 5 to 7 volts, is applied to the select gate line SG1 to turn on the channels of the transistors STa1˜STa3 so that the bit lines BL1˜BI3 couple to the memory cells Qa1˜Qa3. A bias voltage +Vₛₜ, for example, about 5 to 7 volts, is applied to the select gate line SG2 to turn on the channels of the transistors of STb1˜STb3 so that the source line SL couples to the memory cells Qd1˜Qd3 respectively. A bias voltage Vdr, for example, 1 to 2 volts, is applied to the selected bit line BL2 and the non-selected bit line BL1 and BL3 are biased to zero volt The selected word lines WL2 is biased to about zero voltage, and a bias voltage V_{g}, for example, about 5 to 7 volts, is applied to the other none-selected word lines WL1, WL3 and WL4 to turn on the channels of the memory cells. The erase gate lines EG1˜Eg3 are biased to zero voltage. The channels of the memory cells are turned off when the floating gates thereof have charges and the current flowing there-through is small. On the other hand, the channels of the memory cells are turned on when the floating gates thereof do not have charges and the current flow there-through is large. This condition will allow determining whether the digital data in the memory cell is logic 1 or logic 0 by determining the on/off status of the channel on/off and the corresponding large/small current density.

In the foregoing descriptions, a single memory cell is operative in the memory device array, yet the data stored in the NAND flash memory cell array in the present invention can be read by controlling each of the word lines, the select gate lines and the bit lines to read the data present in a byte, a section or a block as a unit.

Hereafter, an ERASE operation of the NAND flash memory cell array according to an embodiment the present invention is described. According to Table 1, the ERASE method of the present invention is exemplary for the entire NAND flash memory cell array.

For ERASING the memory cells, a bias voltage +V_{ge}, for example, about 10 to 20 volts is applied to all erase gate lines EG1 to EG3. The source line SL, the word lines WL1˜WI4, the bit lines BL1˜BL3 and the select lines SG1˜SG2 are floated. Therefore, by applying the voltage between the erase gate and the floating gate, a large electric potential is built so that electrons penetrate through the inter-gate dielectric layer between the erase gate and the floating gate via F-N tunneling effect into the erase gate where the electrons combine with the holes present therein.

According to another embodiment of the present invention, the NAND flash memory cell array can be erased by controlling each of the erase gate lines, wherein data present in a section or a block is treated as a unit. For example, if the erase gate EG1 is selected to be erased, only data in memory cells Qa1˜Qa3, and Qb1˜Qb3 are removed. That is, the data in two memory columns that jointly use the same erase gate line will be erased.

Moreover, when the NAND flash memory cell array is in operation, electrons penetrating through the tunneling dielectric layer via F-N tunneling effect into the floating gate is for PROGRAMMING the memory cells. Whereas, electrons that penetrate through the inter-gate dielectric layer from the floating gate to the erase gate via F-N tunneling effect is for ERASING the memory cells. Since comparatively lesser electrons penetrate through the tunneling dielectric, and therefore the lifetime of tunneling dielectric layer can be extended, and also the reliability of the device is increased. Because electron injection efficiency is higher via F-N tunneling effect during PROGRAM operation, the current of the memory cell is lowered, and therefore operating speed is enhanced. Furthermore, as both the PROGRAM and ERASE operations are accomplished via F-N tunneling effect, and therefore the overall power consumption of the memory device is accordingly reduced.

Hereafter, a structure of the NAND flash memory cell array according to an embodiment of the present invention is described.

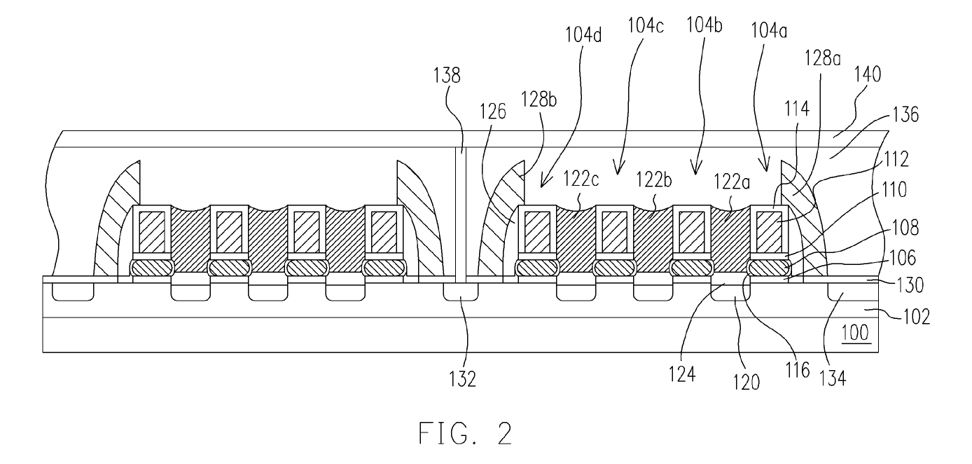

FIG. 2 is a cross-sectional diagram illustrating a structure of the NAND flash memory cell array according to an embodiment of the present invention. A source line jointly used by two rows of memory cells is illustrated in FIG. 2, where one row includes four memory cells. In the following description, only one memory cell is considered.

Referring to FIG. 2, the structure of the NAND flash memory cell array comprises at least a substrate 100, a P-well region 102, a plurality of gate structures 104a˜104d, a doped region (source/drain) 120, a plurality of erase gates 112a˜122c, a dielectric layer 124, a spacer 126, select gates 128a˜128b, select gate dielectric layer 130, source region 132, a drain region 134, an inter-layer dielectric layer 136, a plug 138, and a source line 140.

The substrate 100 is a silicon substrate, for example, and the P-well region102 is disposed in the substrate 100.

The gate structures 104a˜104d are formed over the substrate 100. Each of the gate structures 104a˜104d comprises a tunneling dielectric layer 106, a floating gate 108, a inter-layer dielectric layer 110 and a control gate 112 sequentially A spacer 114 is disposed covering a top and sidewalls of each of the gate structures 104a˜104d of the control gate 112, for example. A spacer 116 is disposed on the sidewalls of the floating gate 108, for example.

A plurality of doped regions (source/drain regions) 120 are disposed in the substrate 100 between the gate structures 104a˜104d, for example, and the gate structures 104a˜104d are connected in series.

The dielectric layers 124 are disposed at over the doped regions (source/drain regions) 120, that is, over the substrate 100 between the gate structures 104a˜104d. The spacer 126 is disposed on the sidewalls of the gate structures 104a and 104d.

A plurality of erase gates 128a˜128b are disposed over the doped regions (source/drain regions) 120 between the gate structures 104a˜104d, for example. Wherein the dielectric layer 124 is disposed between the erase gate 122a˜122c and the doped region (source/drain regions) 120.

The select gate 128a and the select gate 128b are respectively disposed on the sidewalls of the outermost gate structures 104a and 104d. The select gate dielectric layer 130 is disposed between the select gate 128a (select gate 128b) and the substrate 100.

The source region 132 is disposed adjacent to the select gate 128b in the substrate 100 apart from the gate 104d.

The inter-layer dielectric layer 136 is disposed over the substrate 100 covering the NAND flash memory cell. The plug 138 is formed in the inter-layer dielectric layer 136 connecting to the source region 132. A source line 140 is disposed over the inter-layer dielectric layer 136, and is coupled to the source region 132 via the plug 138.

In the foregoing NAND flash memory cell, the erase gates 122a-122c are disposed over the doped regions (source/drain regions) 120. Therefore, when the memory cells are performing the ERASE operation, electrons are drawn from the floating gate into the erase gates 122a˜122c.

Compared to the conventional scheme, the electrons are drawn from the erase gates instead of the substrate via tunneling oxide, and therefore the deep N-well region in the substrate or the exposed N-well region on peripheral of the array are required. Thus, the structure of the NAND memory cell according to the present invention allows further integration of the device.

Moreover, one of the erase gates 122a˜122c is jointly used by adjacent gates structures of the gate structures 104a˜104d , thus the structure of the flash memory cells do not occupy extra space.

In the foregoing embodiment, four memory cell structures are connected in series by a bit line, as an example herein. However, it is to be understood that in actual practice, for example, on bit line is able to connect 32 to 64 memory cell structures.

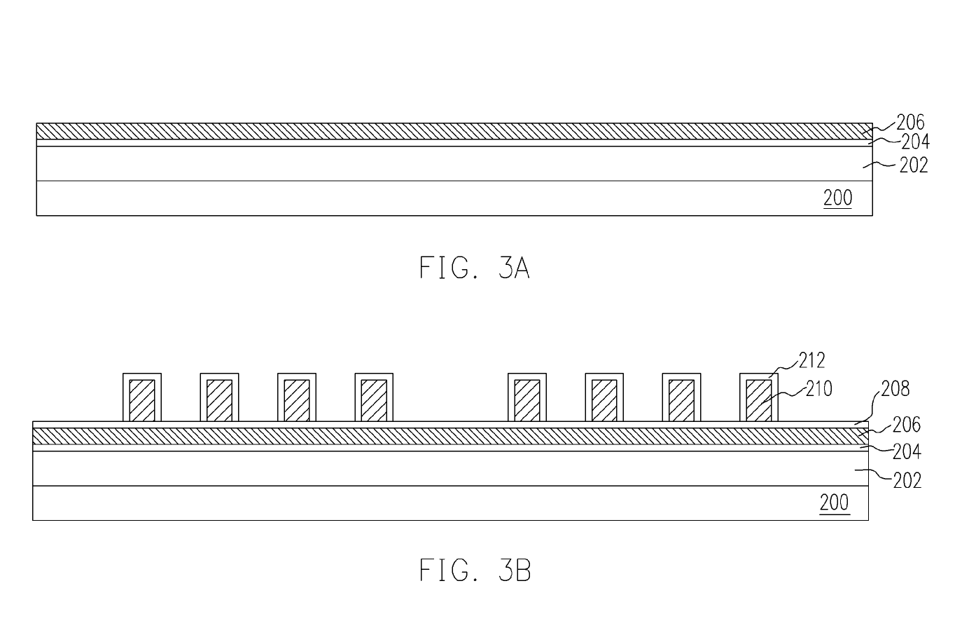

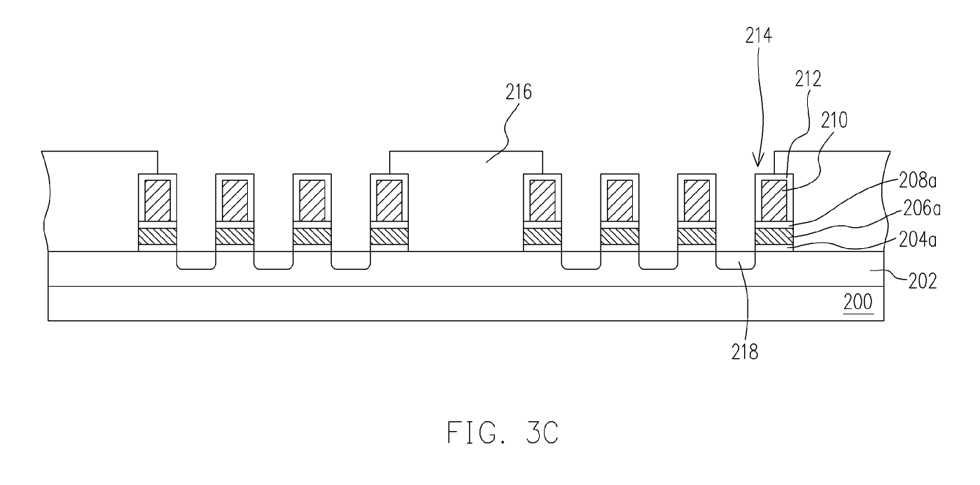

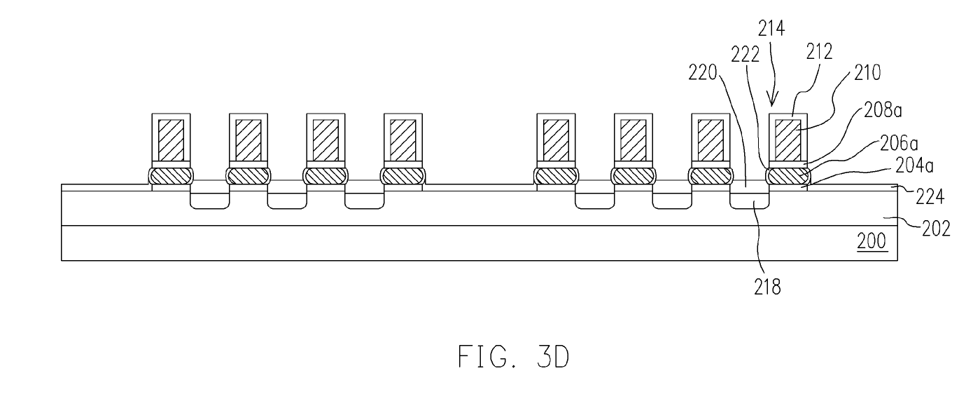

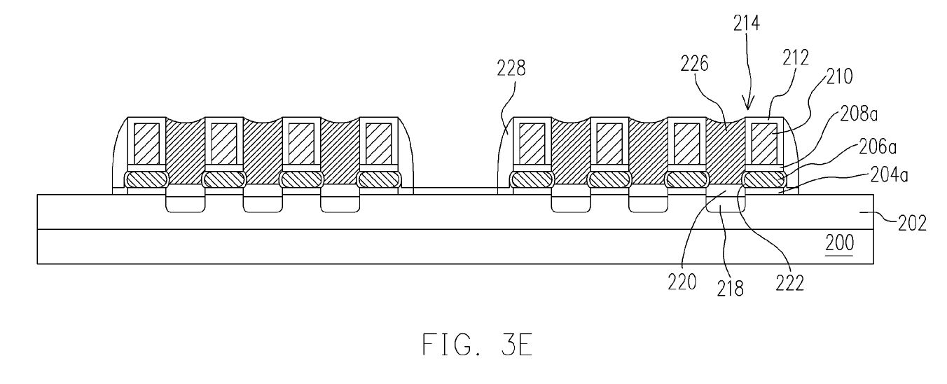

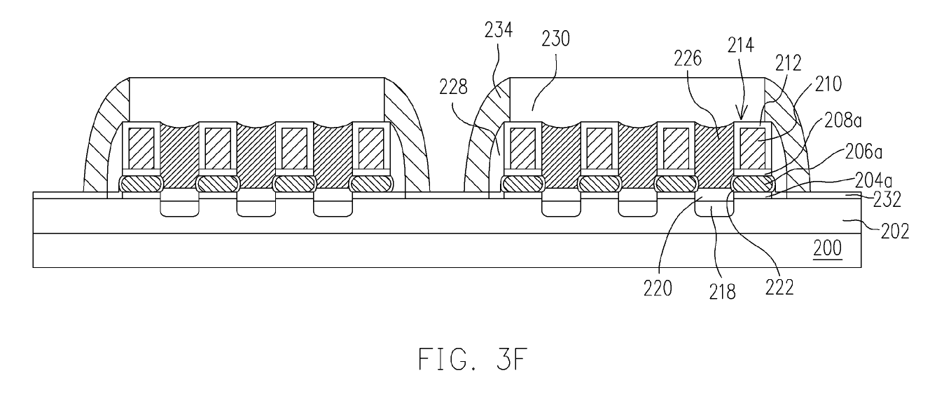

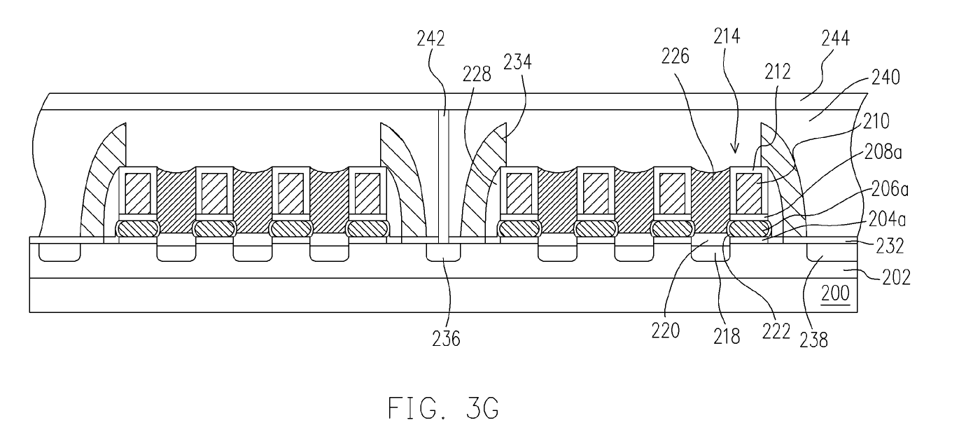

Hereinafter a method of fabricating a NAND flash memory cell array is described with reference to FIGS. 3A and 3G. Moreover, the FIGS. 3A and 3G are described in the light of the fabrication process of the active regions.

Referring to FIG. 3A, a substrate 200 is provided, wherein a device isolation structure is formed (not shown) in the substrate in order to define the active regions. A P-well region 202 is formed in the substrate 200. Thereafter, a tunneling dielectric layer 204 is formed over the surface of the substrate 200. For example, the tunneling dielectric layer 204 comprises a silicon oxide layer. For example, the tunneling dielectric layer 204 is formed by performing a thermal oxidation process. For example, the thickness of the oxide is about 85 Å to 110 Å.

Moreover, a conductive layer 206 is formed over the tunneling dielectric layer 204. For example, the conductive layer 206 is comprised of multiple strips. For example, the material of the conductive layer 206 is comprised of a doped polysilicon layer. For example, the conductive layer 206 is formed by first forming a layer of un-doped polysilicon over the tunneling dielectric layer 204 via chemical vapor deposition (CVD), and then implanting suitable ions into un-doped polysilicon layer. A thickness of the conductive layer 206 is, for example, about 200 Å to 500 Å, and the ions implanted into the un-doped polysilicon layer is, for example, arsenic.

Referring to FIG. 3B, an inter-gate dielectric layer 208 is formed over the substrate 200. For example, the inter-gate layer 208 is comprised of a silicon oxide/silicon nitride/silicon oxide (ONO) composite layer, and the thickness of each of the layers ONO composite layer are 50 Å to 80 Å, 40 Å to 70 Å, and 30 Å to 60 Å, respectively. The inter-gate dielectric 208 is formed, for example, by first forming a silicon oxide layer via thermal oxidation, followed by forming a silicon nitride layer via CVD, and then oxidizing a portion of the nitride silicon layer using H₂/O₂ gas to form a silicon oxide layer. On the other hand, the inter-gate layer 208 can be comprised of a silicon oxide/silicon oxide/silicon nitride (OON) composite layer, and the like.

Next, a plurality of control gates 210 is formed over the inter-gate dielectric layer 208. The control gates can be formed, for example, by first forming a conductive layer over the inter-gate dielectric layer 208 (not shown), and then the conductive layer is patterned via well known photolithography and etching process. The conductive layer 210 is comprised of, for example, doped polysilicon, which can be formed, for example, by forming an undoped polysilicon layer via chemical vapor deposition process and then doping suitable ions therein (in-situ ion doping). The patterned photoresist layer is stripped or removed (not shown).

Thereafter, an insulating layer 212 (spacer) is formed covering a top and sidewalls of the control gates 210. The insulating layer 212 (spacer) is, for example, comprised of a silicon oxide layer. For example, the silicon oxide layer is formed by performing a thermal oxidation process. Alternatively, the insulating layer 212 (spacer) can also formed by first depositing an insulating layer, removing a portion of insulating material by an etching process a remaining portion of the insulating material over the top and the sidewalls of the control gates 210. Further, a cap layer may be formed on top of the control gates 210 (not shown), and a spacer may be formed on the sidewalls of the control gates 210.

Referring to FIG. 3C, using the control gates 210 and the insulating layer 212 (spacer) as a mask portions of the inter-gate dielectric layer 208, the conductive layer 206 and the tunneling dielectric layer 204 not covered by the control gates 210 and the insulating layer 212 are etched and removed, so that the remaining portions of the inter-gate dielectric layer 208a the conductive layer 206a and tunneling dielectric layer 204a are formed underneath the control gates 210. Wherein the conductive layer 206a serves as floating gate. That is, the control gate 210, the inter-gate dielectric layer 208a, the conductive layer (floating gate) 206a and the tunneling dielectric layer 204a (tunneling oxide layer) constitute a gate structure 214. Thereafter, a patterned mask 216 is formed over the substrate 200 to expose predetermined regions of the substrate 200. Next, using the patterned mask 216 and the gate structure 214 serve as a mask, ions implanted into the exposed region of the substrate 200 to form doped regions 218 (source/drain regions) between the gate structures 214.

Referring to FIG. 3D, the patterned mask 216 is removed, the dielectric layer 220 is formed over the doped region (source/drain regions) 218 between the gate structures, and a dielectric layer 224 isformedover the substrate 200, and an insulating layer (spacer) 222 is formed on the sidewalls of the conductive layer 206a (floating gate). Wherein, the insulating layer (spacer) 222 serves as inter-gate dielectric layer between the floating gate and the erase gate, which is subsequently formed. The dielectric layer 220, the dielectric layer 224, and the insulating layer (spacer 222) are, for example, comprised of silicon oxide, and the dielectric layer 220, the dielectric layer 224 and the insulating layer (spacer) 222 are formed by performing a thermal oxidation process. For example, a thickness of the dielectric layer 220 is about 330 Å, and preferably in a range of 300 Å to 500 Å.

Referring to FIG. 3E, a conductive layer 226 is formed over the doped region 218 (source/drain region), that is, between the gate structures 214. The conductive layer 226 serves as an erase gate. For example, the material of the conductive layer 226 is comprised of doped polysilicon. The conductive layer (doped polysilicon) is formed over the substrate 200 by performing a chemical vapor deposition process and in-situ ion doping process. It is to be noted any excess conductive layer 226 over gate structures 214 is removed.

Thereafter, a spacer 228 is formed on the sidewalls of the two outermost gate structures 214. The spacer 228 includes, for example, by forming a high temperature oxide (HTO) layer, and then removing a portion of the HTO in an anisotropic etching process, wherein a portion of the dielectric layer 224 is also removed during anisotropic etching process as shown in the FIG. 3E.

Referring to the FIG. 3F, a patterned mask 230 is formed over the substrate 200 covering the conductive layer 226. Thereafter, a select dielectric layer 232 is formed over the substrate 200. The select dielectric layer 232 is, for example, comprised of silicon oxide layer, and a thickness of which is, for example, about 90 Å to 100 Å. The select dielectric layer 232 comprises, for example, a thermal oxide layer.

Further, a conductive layer 234 is formed on the sidewalls of the two outermost gate structures 214. The conductive layer 234 is, for example, comprised of doped polysilicon. The conductive layer 234 is formed, for example, via CVD and ion implantation (not shown). Thereafter, an anisotropic etching process is performed to remove any excess portion of the conductive layer 234. Wherein the conductive layer 234 serves as the select gate of the memory cell.

Referring to FIG. 3G, a source region 236 and a drain region 238 are formed in the substrate 200. The source/drain regions 236/238 are formed by performing an ion implantation process using patterned mask 230 and the conductive layer 234 as a mask. Thereafter, the patterned mask 230 isremoved; and then an inter-layer dielectric layer 240 is formed over the substrate 200. Next, a plug 242 is formed in the inter-layer dielectric layer 240 for electrically coupling the source region 236, and thereafter, a conductive line (source line) is formed over the inter-layer dielectric layer 240. Subsequently, other down-stream-processing can be carried out, detailed description of which are skipped herein.

In the foregoing embodiment, an erase gate is formed on the doped region (source/drain region). Therefore, when the memory cells performs an erase operation, electrons are drawn from the floating gate to the erase gate via F-N tunneling effect.

Moreover, the deep N-well is not required in the substrate according to the present invention, thus exposed N-well on array peripheral is neither required, and device is more integrated accordingly. Furthermore, an erase gate is jointly used by adjacent gate structures; thus volume of the flash memory cells is not increased. On the other hand, for the floating gate is made of polysilicon doped with arsenic, it is beneficial in forming the floating gate and inter-gate dielectric of the after-process erase gate with a circular shape for erase operation.

In the foregoing embodiment of the present invention, only four memory cells are shown as an example to describe the structure of the NAND memory cell array. However, it is to be understood that in practical application, the number of the memory cells variable. For example, a bit line can be serially connected to 32 to 64 memory cell structures.

The above description provides a full and complete description of the embodiments of the present invention. Various modifications, alternate construction, and equivalent may be made by those skilled in the art without changing the scope or spirit of the invention. Accordingly, the above description and illustrations should not be construed as limiting the scope of the invention, which is defined by the following claims.

1. A NAND flash memory cell row, comprising:
a substrate;
a plurality of gate structures, disposed over the substrate, each of the gate structures comprising a tunneling dielectric layer, a floating gate, an inter-gate dielectric layer and a control gate;
a plurality of doped regions, disposed in the substrate between the gate structures, wherein the gate structures are connected in series;
a plurality of erase gates, disposed over the doped regions and between the gate structures;
a plurality of spacers, disposed between the gate structures and the erase gates;
a plurality of dielectric layers, disposed between the erase gates and the doped regions;
a first select gate and a second select gate, disposed on each of the sidewalls of two outermost gate structures respectively;
a plurality of select gate dielectric layers, disposed between the first select gate and the substrate and between the second select gate and the substrate;
a drain region, disposed in the substrate, wherein the drain region is disposed on one side of the first select gate corresponding to the gate structures; and
a source region, disposed in the substrate, wherein the source region is disposed on one side of the second select gate corresponding to the gate structures.

2. The NAND flash memory cell row of claim 1, wherein the erase gate fills up spaces between the gate structures.

3. The NAND flash memory cell row of claim 1, wherein a thickness of the select gate dielectric layer is about 90 Å to 100 Å.

4. The NAND flash memory cell row of claim 1, wherein the inter-gate dielectric layer comprises silicon oxide/silicon nitride/silicon oxide composite layer.

5. The NAND flash memory cell row of claim 1, wherein the floating gate comprises polysilicon layer doped with arsenic.

6. The NAND flash memory cell row of claim 1, wherein a thickness of the dielectric layer is about 300 Å to 500 Å.

7. A NAND flash memory cell array, comprising:
a plurality of memory cell rows, disposed two-dimensionally and arranged in a memory cell array,
wherein each of the memory cell rows comprises:
a substrate;
a plurality of gate structures, disposed over the substrate, wherein each of the gate structures comprises a tunneling dielectric layer, a floating gate, an inter-gate dielectric layer, and a control gate disposed on the substrate successively;
a plurality of doped regions, disposed between the gate structures in the substrate, wherein the gate structures are connected in series;
a plurality of erase gates, disposed over the doped regions and between the gate structures;
a plurality of spacers, disposed between the gate structures and the erase gates;
a plurality of dielectric layers, disposed between the erase gates and the doped regions;
a first select gate and a second select gate, disposed on each of the sidewalls of the two outermost gate structures respectively;
a plurality of select gate dielectric layers, disposed between the first select gate and the substrate, and the second select gate and the substrate;
a drain region, disposed in the substrate, wherein the drain region is on one side of the first select gate corresponding to the gate structures; and
a source region, disposed in the substrate, wherein the source region is on one side of the second select gate corresponding to the gate structures;
a plurality of word lines, arranged in parallel along column direction, and each of the word lines is coupled to the control gates of the gate structures in a column;
a plurality of bit lines, arranged in parallel along row direction, each of the bit lines is coupled to the drain region of the first select gate in a row;
a source line, coupled to the source regions of the second select gates in the same column respectively; and
a plurality of erase gate lines, arranged in parallel along column direction, and coupled to the erase gates in the same column.

8. The NAND flash memory cell array of claim 7, wherein the erase gate fills up spaces between the gate structures.

9. The NAND flash memory cell array of claim 7, wherein a thickness of the select gate dielectric layer is about 90 Å to 100 Å.

10. The NAND flash memory cell array of claim 7, wherein the inter-gate dielectric layer comprises silicon oxide/silicon nitride/silicon oxide composite layer.

11. The NAND flash memory cell array of claim 7, wherein the floating gate comprises polysilicon layer doped with arsenic.

12. The NAND flash memory cell array of claim 7, wherein a thickness of the dielectric layer is about 300 Å to 500 Å.

13. A method of fabricating a NAND flash memory cell array, comprising:
providing a substrate;
forming a plurality of gate structures over the substrate, wherein the gate structures are formed in a row, and each of the gate structure comprises a tunneling dielecletric layer, a floating gate, an inter-gate dielectric layer and a control gate sequentially disposed on the substrate;
forming a plurality of doped regions in the substrate between the gate structures;
forming a plurality of dielectric layers on the doped regions, and forming a plurality of first spacers on each of the sidewalls of the floating gates;
forming a plurality of erase gates between spaces of the gate structures;
forming a plurality of second spacers on each of the sidewalls of two outermost gate structures;
forming a plurality of first select gates and a plurality of second select gates on each of the sidewalls of the second spacers;
forming a drain region in the substrate, wherein the drain region is disposed on one side of the first select gates corresponding to the gate structures; and
forming a source region in the substrate, wherein the source region is disposed on one side of the second select gates corresponding to the gate structures and the source region is coupled to a source line.

14. The method of claim 13, wherein the step of forming the gate structures comprises:
forming a first dielectric layer over the substrate;
forming a first conductive layer over the first dielectric layer;
forming a second dielectric layer over the first conductive layer;
forming a second conductive layer over the second dielectric layer;
patterning the second conductive layer to form the control gate; and
patterning the second dielectric layer, the first conductive layer, and the first dielectric layer, to form the gate dielectric layer, the floating gate and the tunneling dielectric layer.

15. The method of claim 14, wherein the method further comprisesa step of forming a plurality of third spacers on top and sidewalls of the control gates after the step of forming the control gates and before the step of forming the inter-gate dielectric layers, the floating gates and the tunneling dielectric layers.

16. The method of claim 15, wherein the method of forming the third spacers on top and sidewall of the control gates comprises a thermal oxidation.

17. The method of claim 15, wherein the step of forming the inter-gate dielectric layers, the floating gates and the tunneling dielectric layersuses the control gates and the third spacers as self-alignment masks.

18. The method of claim 13, wherein the step of forming the dielectric layer on the doped regions, and the step of forming the first spacers on sidewall of the floating gate comprise thermal oxidation.

19. The method of claim 13, wherein the step of forming the select gate dielectric layers over the substrate comprises thermal oxidation.

20. The method of claim 13, wherein the floating gate comprises polysilicon layer doped with arsenic.

21. A method operating of a NAND flash memory cell array, the memory cell array comprising a plurality of memory cell rows, the memory cell in each of the memory rows being connected in series between a first select transistor and a second select transistor, each of the memory cells comprising a substrate, a tunneling dielectric layer, a floating gate, an inter-gate dielectric layer, a control gate, and a source/drain region, an erase gate being disposed between every two adjacent memory cells, a plurality of word lines being arranged in parallel along column direction and coupling to the control gates of the memory cells that are in same columns, a source line respectively coupling to source of the first select transistor in the same column, a plurality of bit lines respectively coupling to drain of the second select transistor, a first select gate line coupling to gate of the first select transistor that are in the same column, a second select gate line coupling to gate of the second select transistor of the same column, a plurality of erase gate lines being arranged in parallel along column direction and coupling to the erase gates in the same column, the operating method comprising:
for performing programming, zero voltage is applied to selected bit line, a first voltage is applied to non-selected bit line, a second voltage is applied to the first select gate line, a third voltage is applied to the word line of selected memory cell, a fourth voltage is applied to non-selected word line so as to program the selected memory cell via Fowler-Nordheim tunneling effect;
for performing read operation, a fifth voltage is applied to selected bit line, a sixth voltage is applied to the first select gate line, zero voltage is applied to the word line of selected memory cell, a seventh voltage is applied to non-selected word line so as to read the memory cell; and
for performing erase operation, an eighth voltage is applied to the erase gate line, a difference between the eighth voltage and voltage of the substrate is sufficient to remove electrons that are injected to the floating gate of the memory cell from the erase gateso as to erase the memory cell array.

22. The operating method of claim 21, wherein the first voltage is about 5 to 7 volts.

23. The operating method of claim 21, wherein the second voltage is about 10 to 20 volts.

24. The operating method of claim 21, wherein the third voltage is about 10 to 20 volts.

25. The operating method of claim 21, wherein the fourth voltage is about 5 to 7 volts.

26. The operating method of claim 21, wherein the fifth voltage is about 1 to 2 volts.

27. The operating method of claim 21, wherein the sixth voltage is about 5 to 7 volts.

28. The operating method of claim 21, wherein the seventh voltage is about 5 to 7 volts.

29. The operating method of claim 21, wherein the eighth voltage is about 10 to 20 volts.
